(19) United States
(12) Patent Application Publication
(10) Pub. No.: US 2003/0020163 A1
(43) Pub. Date: Jan. 30, 2003

(54) Bonding pad structure for copper/low-k dielectric material BEOL process

(76) Inventors: Cheng-Yu Hung, Taipei City (TW); Sung-Hsiung Wang, Kaohsiung (TW); Kun-Chih Wang, Hsin-Chu City (TW)

Correspondence Address: POWELL, GOLDSTEIN, FRAZER & MURPHY LLP, P.O. BOX 97223, WASHINGTON, DC, 20090-7223, US

(21) Appl. No.: 09/912,838

(22) Filed: Jul. 25, 2001

(51) Int. Cl. H01L 23/48; H01L 29/40

(52) U.S. Cl. 257/734; 257/780; 257/784; 257/774

(57) ABSTRACT

A bonding pad structure for copper/low-k dielectric material back end of the line (BEOL) processes is disclosed. The bonding pad structure uses a dielectric layer and a conductive pad formed by a gap fill process to protect the underlying bonding pad structure. The conductive pad has a plurality of via plugs in the dielectric layer connecting the underlying bonding pad structure. The bonding pad structure also has a passivation layer having a pad window with a smooth contour to expose the conductive pad.

### BACKGROUND OF THE INVENTION

1. Field of the Invention

The present invention relates to a bonding pad structure of a semiconductor device, and more particularly to a bonding pad structure of a semiconductor device for copper/low-k dielectric material back end of the line (BEOL) processes.

2. Description of the Related Art

In semiconductor manufacturing, a fabricated integrated circuit (IC) device is usually assembled into a package to be utilized on a printed circuit board as part of a larger circuit. In order for the leads of the package to make electrical contact with the bonding pads of the fabricated IC device, the metal bond is formed to make a connection between the bonding pad of the IC device and a lead extending to the package lead frame, or a solder ball connection to a ceramic or polymeric chip carrier.

In the past, aluminum and aluminum alloys have been used as conventional chip wiring materials. Aluminum wiring material is replaced by copper and copper alloys since copper wiring provides improved chip performance and superior reliability when compared to Aluminum and alloys of Aluminum. However, the packaging of IC devices employing copper wiring presents a number of technical issues related to the reaction of copper with materials used in the solder-ball process and/or susceptibility of copper to environmental attack and corrosion.

A typical prior art fabricated IC structure before interconnecting with a package is shown in FIG. 1A. Specifically, the fabricated prior art IC structure shown in FIG. 1A comprises a semiconductor wafer 10 having at least one Cu wiring region 12 embedded in its surface. It is noted that semiconductor wafer 10 includes a plurality of IC device regions therein. For clarity, these IC device regions are not shown in the drawing. The prior art IC structure of FIG. 1A further includes a passivating layer 14 formed on the surface of semiconductor wafer 10 having an opening therein. In the opening, there is shown a terminal via barrier layer 16. A second passivating layer 18 typically composed of an organic material having an opening over Cu wiring 12 is located on the surface of passivating layer 14.

The prior art structure shown in FIG. 1A is normally fabricated by providing a planarized IC wafer containing Cu wiring therein; forming a passivating layer on the surface of the planarized IC wafer; reactive ion etching (RIE) the passivating layer to form terminal via openings over the underlying Cu wiring; providing a barrier layer to said terminal via opening; forming an organic passivating layer on the surface of the barrier layer; and then etching the outer passivating layer to provide an opening to the Cu wiring.

In current practice, large (90 micron) terminal via openings are formed in passivating layer 14 to expose pads that are created at the underlying Cu wiring level. This process that is utilized in the prior art for Cu back-of-the-line (BEOL) structures was developed from previous BEOL technology wherein wirebond connections are made directly through the terminal via openings to the underlying Cu wiring. For current applications where additional Cu wiring levels are being employed, there are several problems with using the above technology.

First, since copper does not form a self-passivating oxide layer as does aluminum, copper exposed to atmospheric conditions will corrode to a depth of several thousand angstroms degrading the reliability of the IC device. Second, for the solder-ball application, the commonly used ball-limiting or barrier metallurgies may not be compatible with copper metallization and might allow the mixing of the lead-tin (Pb—Sn) solder material with the underlying copper. In this event, brittle Cu—Sn intermetallics will form increasing the electrical resistivity and compromising the reliability of the interconnection scheme.

In order to solving the problem set forth, an aluminum layer is formed over the copper pad layer and then is patterned by using sizing-up of the pad window pattern to form an aluminum pad as shown in FIG. 1B and FIG. 1C. However, there are still drawbacks resulting in reliability issues for this type of pad structure. First, the aluminum layer 120 likely peels and the copper pad layer underneath is sequentially exposed to the atmospheric conditions. Second, as shown in FIG. 1B and FIG. 1C, owing to the conformal growth of the aluminum layer 120 and the large (90 micron) terminal via opening, the corner portions of the aluminum layer 120 conventionally formed by a physical vapor deposition (PVD) method easily crack. Furthermore, the aluminum layer 120 and the copper pad layer 114 beneath are likely alloyed and copper atoms could diffuse out. Most important, for copper/low-k dielectric materials BEOL process, bonding forces are usually transferred to the underlying bonding pad structure amid packaging processes and cause serious damages due to the weak adhesion of the soft low-k dielectric materials. As shown in FIG. 1B, the bonding pad structure shows cracks at conductive plug layers 106 and 112 and peeling at the copper layer 114/conductive plug layer 112 interface, the copper layer 110/conductive plug layer 112 interface and the copper layer 110/conductive plug layer 106 interface during a ball-shear bonding test or solder ball packaging. The conductive plug layers 106 and 112 comprise a plurality of conductive plugs connecting the copper layers 102, 108 and 114 and low-k dielectric layers. In FIG. 1B, a substrate 100, low-k dielectric layers 104, 110 and 116, a passivation layers 118, and an aluminum layer 120 are also shown. The same bonding pad structure is also shown in FIG. 1C, wherein peeling appear at the copper layer/the low-k dielectric layer interfaces during a wire-pull bonding test or wire bonding packaging. FIG. 1D, which is the top view of the bonding pad structure shown in FIG. 1B and FIG. 1C, shows the sharp corners where the aluminum layer 120 could cracks amid the wire bonding process. Especially, as shown in FIG. 1B and FIG. 1C, because the aluminum layer 120 is formed by using a conformal growth such as sputtering and the large (90 micron) terminal via opening, cracks easily appear at the “bird' beak” shown in FIG. 1B and FIG. 1C. As the aluminum layer 120 cracks at the sharp corners, the aluminum layer 120 and the copper layer 114 could be alloyed and copper atoms could diffuse out. The troubling issues set forth all degrade the reliability and quality of the packaging.

In view of the drawbacks mentioned with the prior art process of a packaging connection on copper wiring IC structures, there is a continued need to develop new and improved processes that overcome the disadvantages associated with prior art processes. The requirements of this structure are that it be compatible with conventional chip packaging and test methodologies and that it protects the bonding pad structure from the threats mentioned above.

### SUMMARY OF THE INVENTION

It is therefore an object of the invention to provide a bonding pad structure for copper/low-k dielectric material BEOL processes which can prevent the copper pad layer from exposing to the atmospheric conditions as the aluminum layer above peeling during the packaging processes and testing.

It is another object of this invention to provide a bonding pad structure for copper/low-k dielectric material BEOL processes which can prevent the bonding forces from being directly transferred to the underlying bonding pad structure and thus causing serious damages.

It is a further object of this invention to provide a bonding pad structure for copper/low-k dielectric material BEOL processes which can avoid conductive plug layer cracks and peeling problems in copper/low-k dielectric material interfaces.

To achieve these objects, and in accordance with the purpose of the invention, the invention uses a bonding pad structure comprising: a substrate having a first dielectric layer thereon; a conductive layer embedded in said first dielectric layer; a second dielectric layer over said first dielectric layer and said conductive layer; a plurality of via plugs in said second dielectric layer; a conductive pad on said second dielectric layer and connected to said conductive layer by said via plugs; and a passivation layer over said conductive pad and said second dielectric layer having a opening to expose a portion of said conductive pad.

In another embodiment of this invention, the invention uses a bonding pad structure comprising: a substrate; a first low dielectric constant dielectric layer having a plurality of conductive plugs therein on said substrate; a second low dielectric constant dielectric layer on said first low dielectric constant dielectric layer; a conductive layer embedded in said second low dielectric constant dielectric layer and connecting to said conductive plugs; a silicon dioxide layer over said second low dielectric constant dielectric layer and said conductive layer; a plurality of via plugs in said silicon dioxide layer; a conductive pad on said silicon dioxide layer and connected to said conductive layer by said via plugs; and a combination layer of silicon dioxide and silicon nitride over said conductive pad and said silicon dioxide layer having a circular opening to expose a portion of said conductive pad.

It is to be understood that both the foregoing general description and the following detailed description are exemplary and explanatory only and are not restrictive of the invention, as claimed.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A shows a cross-sectional diagram of a conventional bonding pad structure;

FIG. 1B shows a cross-sectional diagram of another conventional bonding pad structure having cracks and peeling;

FIG. 1C shows a cross-sectional diagram of the conventional bonding pad structure shown in FIG. 1B having peeling;

FIG. 1D shows the top view of the bonding pad structure shown in FIG. 1B and FIG. 1C

FIG. 2A shows a dielectric layer formed on a bonding pad structure;

FIG. 2B shows a conductive layer formed on the bonding pad structure shown in FIG. 2A by a gap fill process;

FIG. 2C shows a cross-sectional diagram of a bonding pad structure of this invention; and

FIG. 2D shows the top view of the bonding pad structure shown in FIG. 2C.

### DESCRIPTION OF THE PREFERRED EMBODIMENT

It is to be understood and appreciated that the process steps and structures described below do not cover a complete process flow. The present invention can be practiced in conjunction with various integrated circuit fabrication techniques that are used in the art, and only so much of the commonly practiced process steps are included herein as are necessary to provide an understanding of the present invention.

The present invention will be described in detail with reference to the accompanying drawings. It should be noted that the drawings are in greatly simplified form and they are not drawn to scale. Moreover, dimensions have been exaggerated in order to provide a clear illustration and understanding of the present invention.

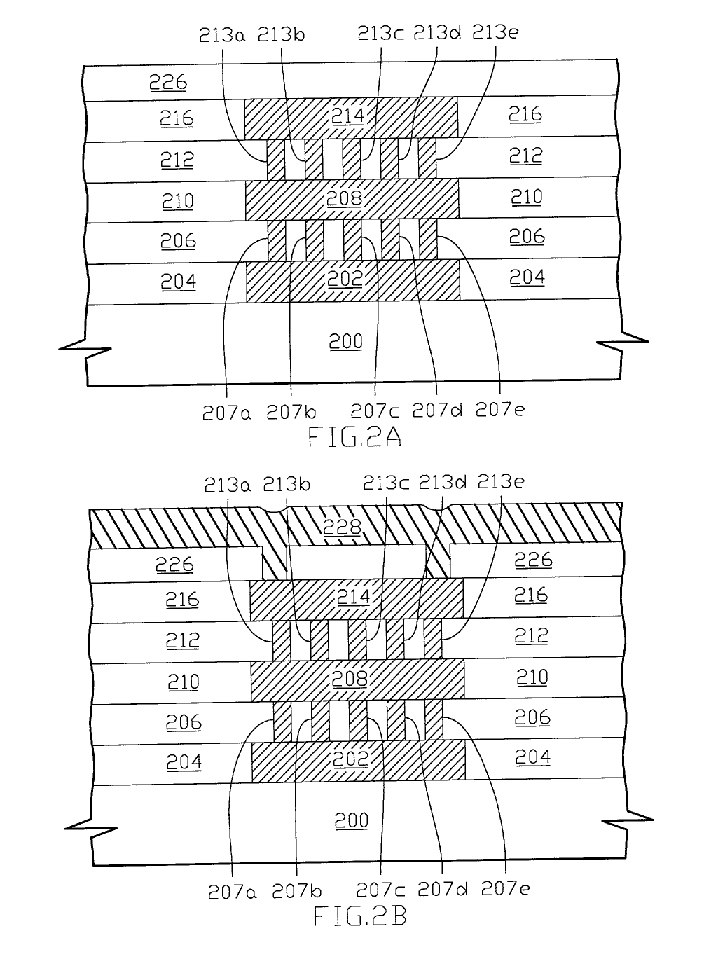

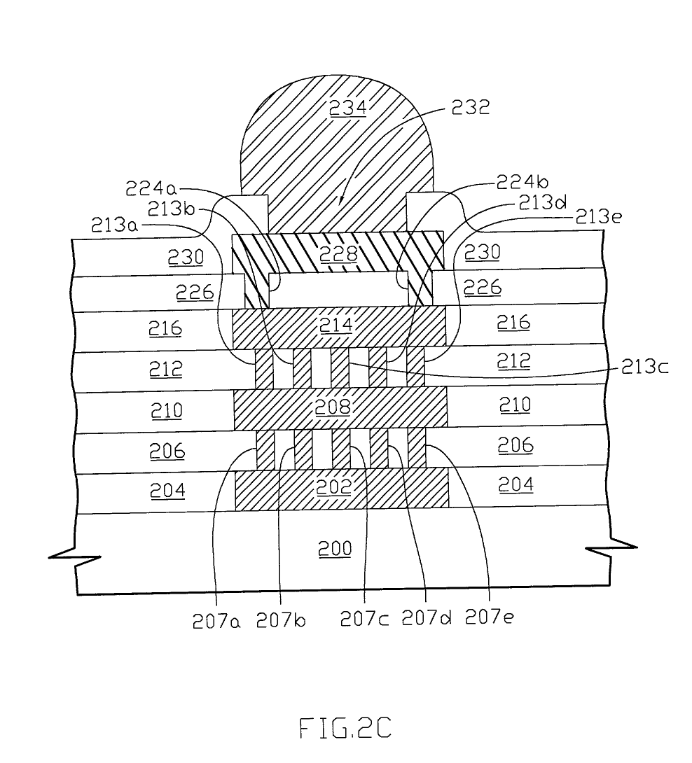

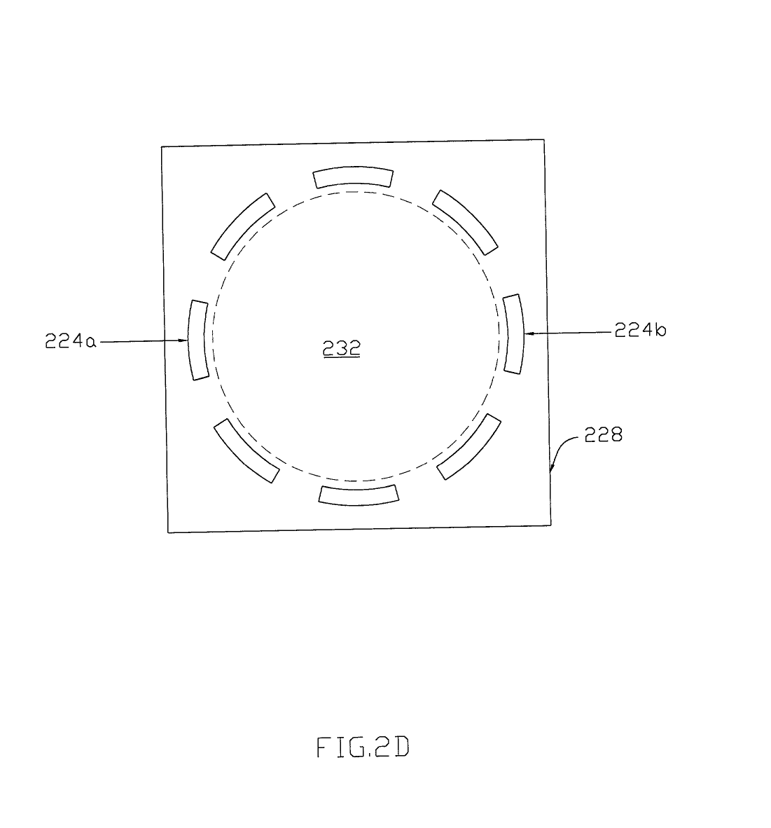

Referring to FIG. 2A, a bonding pad structure having a dielectric layer 226 thereon is shown. The bonding pad structure comprises a substrate 200, conductive layers 202, 208 and 214, conductive plugs 207a-207e and 213a-213e, dielectric layers 204, 206, 210, 212 and 216, and a dielectric layer 226. The substrate 200 comprises a semiconductor wafer comprising a plurality of IC device regions therein which are not shown for simplicity, and the semiconductor wafer preferably comprises, but is not limited to: a silicon wafer. The semiconductor wafer can also comprise dielectric materials such as silicon dioxide and diamond-like carbon as well as germanium, gallium arsenide and indium arsenide. The Conductive layers 202, 208 and 214 preferably comprise, but are not limited to: coppers layers and copper alloy layers. The conductive layers 202, 208 and 214 can also be aluminum layers and aluminum alloy layers. More particularly, the method used to form the conductive layers 202, 208 and 214 comprises, but is not limited to: a dual damascene process. The conductive layers 202, 208 and 214 can also be formed by using physical vapor deposition, chemical vapor deposition, electro-chemical deposition and chemical mechanical polishing. The thicknesses of the conductive layers 202, 208 and 214 are from about 2500 angstrom to about 8000 angstrom. The conductive plugs 207a-207e and 213a-213e are preferably, but are not limited to: copper plugs and copper alloy plugs. Other conductive materials such as aluminum, aluminum alloys and tungsten can also be used. The conductive plugs 207a-207e and 213a-213e can be formed by using conventional techniques such as dry etching, wet etching, physical vapor deposition, chemical vapor deposition and dual damascene process. The dielectric layers 204, 206, 210, 212 and 216 preferably comprise, but are not limited to: low-k dielectric layers such as a silk layer, a fluorosilicate glass (FSG) layer, a hydrogen silsesquioxane (HSQ) layer and a methyl silsesquioxane (MSQ) layer. Other dielectric materials such as silicon dioxide and silicon nitride can also be used. The dielectric layers 204, 206, 210, 212 and 216 can be formed by using any conventional technique such as physical vapor deposition, chemical vapor deposition and chemical mechanical polishing. The dielectric layers 204, 206, 210, 212 and 216 have a thickness of from about 2500 angstrom to about 8000 angstrom. The dielectric layer 226 preferably comprises, but is not limited to: a silicon dioxide layer. A silicon nitride layer and a combination layer of silicon dioxide and silicon nitride can also be used. The method used to form the dielectric layer 226 preferably comprises, but is not limited to: by a plasma enhanced chemical vapor deposition. Other conventional deposition method such as physical vapor deposition and chemical vapor deposition can be used. The dielectric layer 226 has a thickness of from about 10000 angstrom to about 25000 angstrom.

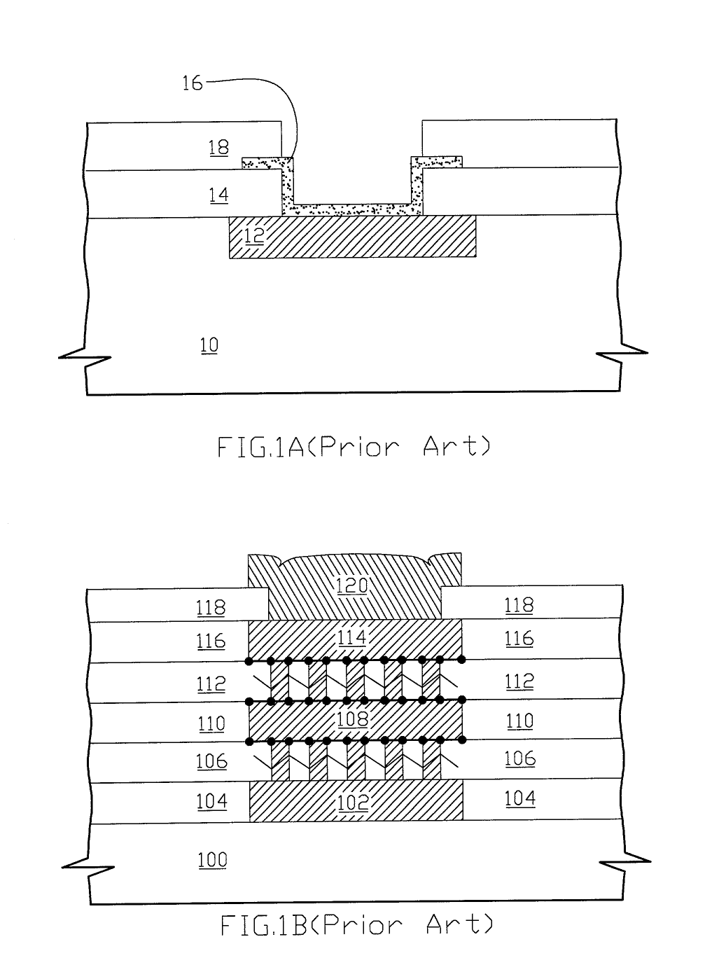

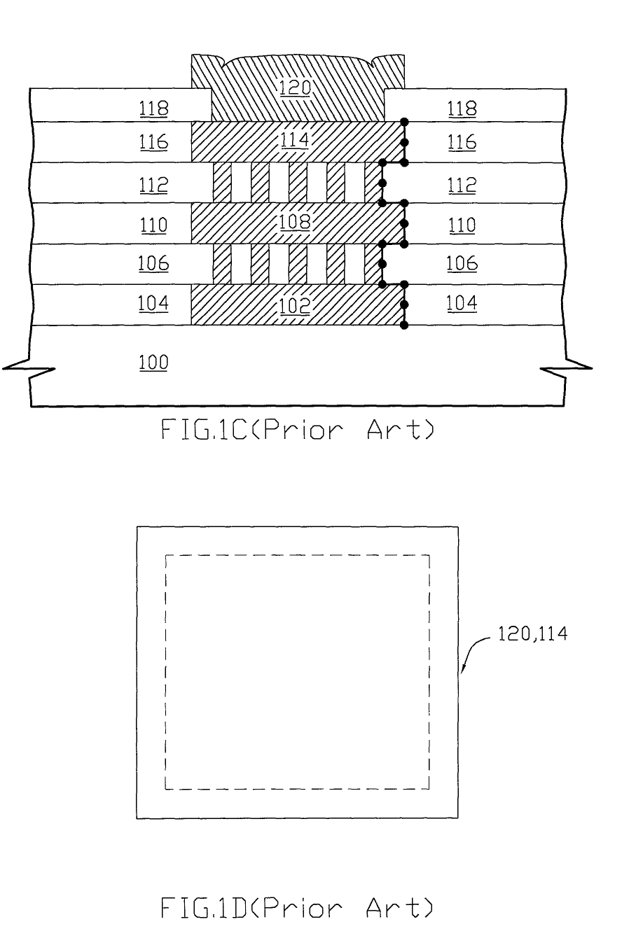

Referring to FIG. 2B, the dielectric layer 226 is etched to form holes or trenches and expose the conductive layer 214, and a conductive layer 228 and via plugs 224a and 224b are formed. A barrier layer comprising a Ti/TiN layer and a Ta/TaN layer is formed previous to the formation of the conductive layer 228, but it is omitted for simplicity here. The dielectric layer 226 is etched preferably by a dry etching process, but other etching methods such as wet etching should not be excluded. The dimension of the holes or trenches is from about 2 micron to about 8 micron, and is preferably about 5 micron. The conductive layer 228 preferably comprises, but is not limited to: an aluminum layer and an aluminum alloy layer. Other conductive materials met the requirements of this invention should not be excluded. The via plugs 224a and 224b are preferably formed together with the conductive layer 228. The method used to form the conductive layer 228 and the via plugs 224a and 224b comprise, but is not limited to: physical vapor deposition. More particularly, instead of conformal growth over a large opening, the conductive layer 228 and the via plugs 224a and 224b are preferably formed by using a gap fill process. With proper process control, the “bird' beak” shown in FIG. 1B and FIG. 1C will not appear thereby prevents the cracks possibly formed at the corners shown in FIG. 1D. The thickness of the conductive layer 228 is from about 10000 angstrom to about 15000 angstrom.

Referring to FIG. 2C, the conductive layer 228 is etched to expose the dielectric layer 226 and form the bonding pad 228, and a passivation layer 230 is formed thereon and etched to form a pad window 232. Furthermore, a controlled collapse chip connection (C4) pad or bump structure 234 is formed to connect the bonding pad 228. The method used to etch the conductive layer 228 comprises dry etching and wet etching, and it is preferably a dry etching method. The top view of the bonding pad 228 is shown in FIG. 2D. The passivation layer 230 comprises a silicon dioxide layer, a silicon nitride layer, a SiO₂ and Si₃N₄ layer, a Si₃N₄, SiO₂ and Si₃N₄ layer and a SiO₂, Si₃N₄ and SiO₂ layer. The passivation layer 230 can be formed by using conventional methods such as chemical vapor deposition and physical vapor deposition, and it is preferably a plasma enhanced chemical vapor deposition process. The thickness of the passivation layer 230 is from about 10000 angstrom to about 15000 angstrom. The pad window 232 is formed by using conventional methods such as photolithography, dry etching and wet etching. The contour of the pad window 232 comprises, but it is not limited to: a circle. Other geometrical contours without any sharp corner should not be excluded. The diameter of the pad window 232 is about 40 micron to about 90 micron. The plated C4 pad or bump structure 234 connects directly to the bonding pad 228 through the pad window 232. The bump structure 234 comprises Pb—Sn solder and is provided on integrated circuit chips for making interconnections to substrates.

The invention modifies the pad structure above the top copper layer 114 as shown in FIG. 1B and FIG. 1C which has a square pad window in the passivation layer 118, a sizing-up aluminum pad 120 to a new one having a dielectric layer 226 having the via plugs 224a and 224b connecting the top conductive layer 214 and the bonding pad 228, the bonding pad 228 and a pad window 232 having a contour without any sharp corner in the passivation layer 230 as shown in FIG. 2C. The advantages of this pad structure include: first, during tests such as probing, as the probe penetrates the bonding pad 228 or renders the bonding pad 228 peeling, the dielectric layer 226 can prevent the conductive layer 214 from exposing to the atmospheric conditions. Second, the dielectric layer 226 serving as a buffer layer can effectively degrade the bonding force directly coupling to the underlying pad structure and prevent cracks and peeling during packaging or testing. Third, instead of conformal growth, the bonding pad 228 is formed by gap fill, cracks at sharp corners will not occur. Fourth, because the via plugs connecting the top conductive layer 214 and the bonding pad 228 are uniformly distributed along the contour of the pad window 232, the shear force of packaging or testing will be distributed and dispersed and cracks can be avoided. Fifth, because the dielectric layer 226 is formed over the whole integrated circuit, it can clamp the underlying pad structure and prevent the underlying pad structure from peeling.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

What is claim is:

1. A bonding pad structure of a semiconductor device, said bonding pad structure comprising:
a substrate having a first dielectric layer thereon;
a conductive layer embedded in said first dielectric layer;
a second dielectric layer over said first dielectric layer and said conductive layer;
a plurality of via plugs in said second dielectric layer;
a conductive pad on said second dielectric layer and connected to said conductive layer by said via plugs; and
a passivation layer over said conductive pad and said second dielectric layer having a opening to expose a portion of said conductive pad.

2. The bonding pad structure according to claim 1, wherein said first dielectric layer comprises a low dielectric constant dielectric layer.

3. The bonding pad structure according to claim 1, wherein said conductive layer comprises a copper layer.

4. The bonding pad structure according to claim 1, wherein said conductive layer comprises a copper alloy layer.

5. The bonding pad structure according to claim 1, wherein said dielectric layer comprises a silicon dioxide layer.

6. The bonding pad structure according to claim 1, wherein said dielectric layer comprises a silicon nitride layer.

7. The bonding pad structure according to claim 1, wherein said dielectric layer has a thickness of from about 10000 angstrom to about 25000 angstrom.

8. The bonding pad structure according to claim 1, wherein said via plugs and said conductive pad comprise aluminum plugs and an aluminum pad.

9. The bonding pad structure according to claim 1, wherein said via plugs and said conductive pad comprise aluminum alloy plugs and an aluminum alloy pad.

10. The bonding pad structure according to claim 1, wherein said conductive pad has a thickness of from about 10000 angstrom to about 15000 angstrom.

11. The bonding pad structure according to claim 1, wherein said passivation layer comprises a combination layer of silicon dioxide and silicon nitride.

12. The bonding pad structure according to claim 1, wherein said passivation layer comprises a combination layer of silicon nitride, silicon dioxide and silicon nitride.

13. The bonding pad structure according to claim 1, wherein said passivation layer has a thickness of from about 10000 angstrom to about 15000 angstrom.

14. The bonding pad structure according to claim 1, wherein said opening has a smooth contour.

15. The bonding pad structure according to claim 1, wherein said via plugs array along said opening.

16. A bonding pad structure of a semiconductor device, said bonding pad structure comprising:
a substrate having a low dielectric constant dielectric layer thereon;
a conductive layer embedded in said low dielectric constant dielectric layer;
a dielectric layer over said low dielectric constant dielectric layer and said conductive layer;
a plurality of via plugs in said dielectric layer;
a conductive pad on said dielectric layer and connected to said conductive layer by said via plugs; and
a passivation layer over said conductive pad and said dielectric layer having a circular opening to expose a portion of said conductive pad.

17. The bonding pad structure according to claim 16, wherein said low dielectric constant dielectric layer comprises a hydrogen silsesquioxane (HSQ) layer.

18. The bonding pad structure according to claim 16, wherein said conductive layer comprises a copper layer.

19. The bonding pad structure according to claim 16, wherein said conductive layer comprises a copper alloy layer.

20. The bonding pad structure according to claim 16, wherein said dielectric layer comprises a silicon dioxide layer.

21. The bonding pad structure according to claim 16, wherein said dielectric layer comprises a silicon nitride layer.

22. The bonding pad structure according to claim 16, wherein said dielectric layer has a thickness of from about 10000 angstrom to about 25000 angstrom.

23. The bonding pad structure according to claim 16, wherein said via plugs and said conductive pad comprise aluminum plugs and an aluminum pad.

24. The bonding pad structure according to claim 16, wherein said via plugs and said conductive pad comprise aluminum alloy plugs and an aluminum alloy pad.

25. The bonding pad structure according to claim 16, wherein said conductive pad has a thickness of from about 10000 angstrom to about 15000 angstrom.

26. The bonding pad structure according to claim 16, wherein said passivation layer comprises a combination layer of silicon dioxide and silicon nitride.

27. The bonding pad structure according to claim 16, wherein said passivation layer comprises a combination layer of silicon nitride, silicon dioxide and silicon nitride.

28. The bonding pad structure according to claim 16, wherein said passivation layer has a thickness of from about 10000 angstrom to about 15000 angstrom.

29. The bonding pad structure according to claim 16, wherein said via plugs array along said circular opening.

30. A bonding pad structure of a semiconductor device, said bonding pad structure comprising:
a substrate having a low dielectric constant dielectric layer thereon;
a conductive layer embedded in said low dielectric constant dielectric layer;
a silicon dioxide layer over said low dielectric constant dielectric layer and said conductive layer;
a plurality of via plugs in said silicon dioxide layer;
a conductive pad on said silicon dioxide layer and connected to said conductive layer by said via plugs; and
a combination layer of silicon dioxide and silicon nitride over said conductive pad and said silicon dioxide layer having a circular opening to expose a portion of said conductive pad.

31. The bonding pad structure according to claim 30, wherein said low dielectric constant dielectric layer comprises a methyl silsesquioxane (MSQ) layer.

32. The bonding pad structure according to claim 30 wherein said conductive layer comprises a copper layer.

33. The bonding pad structure according to claim 30, wherein said conductive layer comprises a copper alloy layer.

34. The bonding pad structure according to claim 30, wherein said silicon dioxide layer has a thickness of from about 10000 angstrom to about 25000 angstrom.

35. The bonding pad structure according to claim 30, wherein said via plugs and said conductive pad comprise aluminum plugs and an aluminum pad.

36. The bonding pad structure according to claim 30, wherein said via plugs and said conductive pad comprise aluminum alloy plugs and an aluminum alloy pad.

37. The bonding pad structure according to claim 30, wherein said conductive pad has a thickness of from about 10000 angstrom to about 15000 angstrom.

38. The bonding pad structure according to claim 30, wherein said combination layer of silicon dioxide and silicon nitride has a thickness of from about 10000 angstrom to about 15000 angstrom.

39. The bonding pad structure according to claim 30, wherein said via plugs array along said circular opening.

40. A bonding pad structure of a semiconductor device, said bonding pad structure comprising:
a substrate;
a first low dielectric constant dielectric layer having a plurality of conductive plugs therein on said substrate;
a second low dielectric constant dielectric layer on said first low dielectric constant dielectric layer;
a conductive layer embedded in said second low dielectric constant dielectric layer and connecting to said conductive plugs;
a silicon dioxide layer over said second low dielectric constant dielectric layer and said conductive layer;
a plurality of via plugs in said silicon dioxide layer;
a conductive pad on said silicon dioxide layer and connected to said conductive layer by said via plugs; and
a combination layer of silicon dioxide and silicon nitride over said conductive pad and said silicon dioxide layer having a circular opening to expose a portion of said conductive pad.
